(19) United States
(12) Patent Application Publication
(10) Pub. No.: US 2024/0393275 A1
(43) Pub. Date: Nov. 28, 2024

(54) ACTIVE ELECTROCHEMICAL EXCITATION SYSTEM

(71) Applicant: Analog Devices International Unlimited Company, Limerick (IE)

(72) Inventors: Marc Zwalua, Munchen (DE); Folkert Diederik Roscam Abbing, Munich (DE); Leon Alexander Loopik, Delft (NL); Michael Alfred Kultgen, Denver, CO (US)

(21) Appl. No.: 18/201,063

(22) Filed: May 23, 2023

(51) Int. Cl. G01N 27/02

(52) U.S. Cl. CPC G01N 27/026

(57) ABSTRACT

An electrochemical impedance spectroscopy (EIS) excitation system may include energy transfer circuitry, which may be configured to transfer energy from a first electrochemical device to a second electrochemical device. The EIS excitation system may also include a controller, which may be configured to control the energy transfer circuitry to generate an EIS excitation signal for the first electrochemical device. The controller may be configured to control the energy transfer circuitry to transfer energy in a first direction between the first electrochemical device and the second electrochemical device for a first portion of an EIS excitation signal cycle.

### TECHNOLOGICAL FIELD

The present disclosure relates to electronics, and more particularly, but not by way of limitation, to an electrochemical excitation system that can be used to excite battery cells or other electrochemical cells.

### BACKGROUND

Modern systems can use electrochemical energy storage systems, such as batteries or fuel cells, as a main power source or an auxiliary power source. Examples of such modern systems can include consumer electronics, industrial electronics, passenger cars, and industrial trucks. Monitoring the state of charge (SoC) and the state of health (SoH) of a battery can help ensure reliable operation of the system and avoid unnecessary damage to the battery, such as due to overheating or over-discharging.

### SUMMARY

One approach to estimate the SoC and SoH is electrochemical impedance spectroscopy (EIS). EIS can be used to determine the complex impedance of a cell or group of cells in an electrochemical device. The electrochemical device may include an arrangement of one or more battery cells, one or more fuel cells, one or more electrolysis cells, one or more other electrochemical cells, or any combination thereof. The complex impedance of a cell or group of cells can be determined at a single frequency or at multiple frequencies. The determined complex impedance of the cell or group of cells can be used to obtain information about the SoC and SoH of the cell or group of cells. The determined complex impedance can be used to estimate the charge level of the cell or group of cells. The determined complex impedance can be used to estimate the internal temperature of the battery. Estimation of the internal temperature of the battery can be more useful than measuring the external temperature of the battery, which may not accurately reflect internal temperature, resulting in overheating of the battery. The determined complex impedance can be used to estimate the available capacity of the cell or group of cells relative to new. A complex impedance at a single frequency may be useful for determining one or more measures of SoC or SoH. A complex impedance at multiple frequencies may be useful for determining one or more measures of SoC or SoH.

The present inventors have recognized, among other things, that the need for accurate and predictive battery monitoring systems (BMS) has grown with the interest in increasing use-time, range, and performance of the systems and devices using electrochemical devices. For example, the more that a battery is discharged (e.g., to a lower SoC) or the more a battery is stressed, the more likely the battery is to be damaged if not effectively monitored.

The present inventors have recognized, among other things, that it may be necessary to excite an electrochemical device with an alternating current (AC) of a specified frequency in order to take one or more EIS measurements. In an approach, a resistor may be recurrently coupled and decoupled between terminals of an electrochemical device to generate an AC current. However, this may result in energy loss in resistor, or heat generation by the resistor, or both. Generating an AC excitation current by passing energy from one electrochemical device to another electrochemical device may reduce the amount of energy that is dissipated, reduce the amount of heat that is produced, or both.

The present inventors have recognized, among other things, that a single electrochemical module, such as may include an electric vehicle (EV) battery, may be treated as two or more electrochemical devices if the electrochemical module has two or more cells. For example, a bottom portion of the module may be treated as a first electrochemical device and a top portion of the module may be treated as a second electrochemical device. This may allow for the excitation of the electrochemical module without requiring a separate electrochemical device.

In an example, an electrochemical impedance spectroscopy (EIS) excitation system may include energy transfer circuitry, which may be configured to transfer energy from a first electrochemical device to a second electrochemical device. The EIS excitation system may also include a controller, which may be configured to control the energy transfer circuitry to generate an EIS excitation signal for the first electrochemical device. The controller may be configured to control the energy transfer circuitry to transfer energy in a first direction between the first electrochemical device and the second electrochemical device for a first portion of an EIS excitation signal cycle.

In an example, a method for electrochemical impedance spectroscopy (EIS) excitation may include generating an EIS excitation signal of a specified EIS excitation frequency for a first electrochemical device. The EIS excitation signal may include a carrier signal of a specified carrier frequency. Generating the EIS excitation signal may include transferring energy in a first direction between the first electrochemical device and a second electrochemical device in discrete pulses issued at the specified carrier frequency for a first portion of an EIS excitation signal cycle.

In an example, an electrochemical impedance spectroscopy (EIS) excitation system may include an inductor, which may have a first inductor terminal and a second inductor terminal. The first inductor terminal may be coupled to a first polarity terminal of a first electrochemical device and a second polarity terminal of a second electrochemical device. The EIS excitation system may also include a first switch, which may have a first conduction terminal and a second conduction terminal. The first conduction terminal may be coupled to a second polarity terminal of the first electrochemical device and the second conduction terminal may be coupled to the second inductor terminal. The EIS excitation system may also include a second switch, which may have a third conduction terminal and a fourth conduction terminal. The third conduction terminal may be coupled to a first polarity terminal of the second electrochemical device and the fourth conduction terminal may be coupled to the second inductor terminal.

### BRIEF DESCRIPTION OF THE DRAWINGS

In the drawings, which may not be drawn to scale, like numerals may describe substantially similar components throughout one or more of the views. Like numerals having different letter suffixes may represent different instances of substantially similar components. The drawings illustrate generally, by way of example but not by way of limitation.

FIG. 1 is a schematic drawing of an example of portions of an electrochemical excitation system, including portions of an example of a system in which the electrochemical excitation system may be used.

FIG. 2 is a block drawing of an example of portions of an electrochemical excitation system, including portions of an example of a system in which the electrochemical excitation system may be used.

FIG. 3 is a timing diagram showing an example of operating portions of the electrochemical excitation system of FIG. 1.

FIG. 4 is a graph in time showing an example of operating portions of the electrochemical excitation system of FIG. 1.

FIG. 5 is a diagram showing an example of a method for operating portions of a electrochemical excitation system.

FIG. 6 is a block diagram of an example of portions of a machine upon which one or more portions of the present disclosure may be implemented.

### DETAILED DESCRIPTION

The present disclosure relates to an electrochemical excitation system that can generate an AC signal in one or more electrochemical cells by transferring energy between electrochemical cells.

A complex current or voltage may be associated with a corresponding frequency value, an amplitude value, and a phase value. The frequency value may represent the frequency at which a periodic impedance test signal repeats itself. Frequency may be measured in the number of times the signal repeats itself per second, or hertz (Hz). The amplitude value may represent the size or magnitude of the current or voltage signal. The amplitude value may be measured in amps (A) for current and volts (V) for voltage. The amplitude value may be determined by the peak of the periodic signal, or it may be determined by some other method, such as taking the square root of the mean of the signal squared (RMS). Using an amplitude measured in RMS units may be helpful in determining power dissipation. The phase value may be determined by measuring the position of one signal in time relative to the position of another signal in time. For example, the positive-going zero crossing of a voltage signal may be measured relative to the positive-going zero crossing of a current signal. If the voltage and current signals are aligned in time, the signals may be defined as being in phase, and the phase value may be defined as 0 degrees. If the voltage signal is peaking when the current signal is at its positive zero-crossing, this may be defined as the voltage signal leading the current signal by 90 degrees.

A complex impedance value may have a magnitude and a phase value at a given frequency. A complex impedance value may also be defined in terms of a real component and an imaginary component at a given frequency. A complex impedance value may be determined for a circuit element or a group of circuit elements by dividing a complex voltage value across the circuit element or elements by a complex current value through the circuit element or elements according to equation 1.

Z=V/I Equation 1

In equation 1, Z represents the complex impedance, V represents the complex voltage, and I represents the complex current. The magnitude of the complex impedance value may represent the ratio of the magnitude of the voltage to the magnitude of the current, and the phase of the complex impedance value may represent the difference between the phase of the complex voltage and the phase of the complex current. Because the phase value of the complex impedance represents the relative difference between the phases of the voltage and current, an absolute measure of phase relative to a specific point in time may not be required.

One or more of the complex voltage or complex current may represent an average value of a higher frequency signal. For example, the complex current signal at a desired EIS excitation frequency may be composed of a waveform, such as may include discrete pulses, at a carrier frequency. The carrier frequency may be higher than the EIS excitation frequency. The effect of the carrier frequency may be filtered out to determine the complex impedance at the EIS excitation frequency. For example, an EIS measurement circuit may attenuate an effect of the carrier frequency using analog or digital circuitry, and may analyze the effect of the EIS excitation frequency. One or more properties of EIS conducted using an EIS excitation frequency carried by a carrier frequency may be the same or similar to one or more properties of EIS conducted using an EIS excitation frequency that is not carried by a carrier frequency. One or more properties of EIS conducted using an EIS excitation frequency carried by a carrier frequency may be different than one or more properties of EIS conducted using an EIS excitation frequency that is not carried by a carrier frequency. For example, the determination of one or more of SoC or SoH may have to be adjusted when using an EIS excitation signal carried by a carrier signal.

One or more properties of EIS conducted using an EIS excitation frequency carried by a carrier frequency may be more accurate than one or more properties of EIS conducted using an EIS excitation frequency that is not carried by a carrier frequency. One or more properties of EIS conducted using an EIS excitation frequency carried by a carrier frequency may be less accurate than one or more properties of EIS conducted using an EIS excitation frequency that is not carried by a carrier frequency.

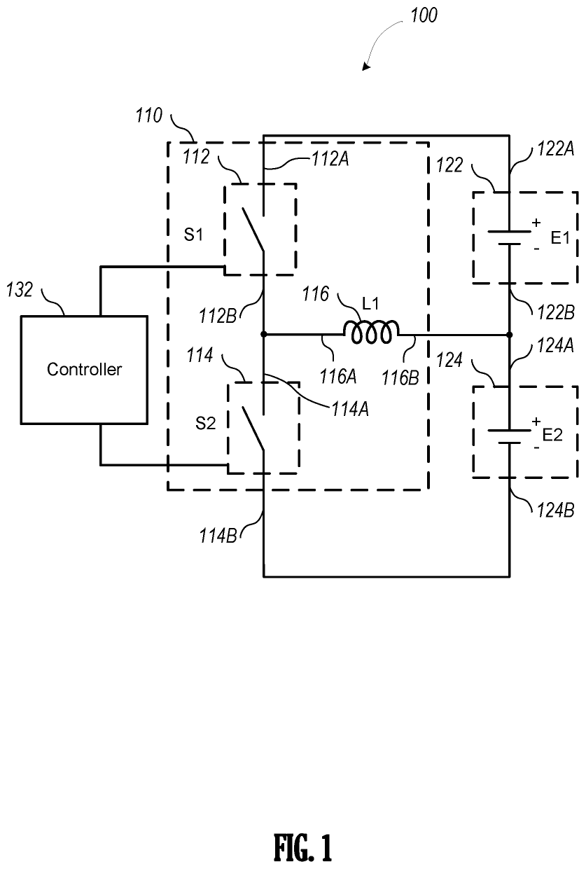

FIG. 1 is a schematic drawing of an example of portions of an electrochemical excitation system 100, including portions of an example of a system in which the electrochemical excitation system may be used. FIG. 1 shows that the electrochemical excitation system 100 may include energy transfer circuitry 110, and a controller 132. The environment in which the electrochemical excitation system 100 may be used may include a first electrochemical device 122 and a second electrochemical device 124.

The first electrochemical device 122 may include an electrochemical cell, such as may be configured to one or more of store, generate, accept, or convert energy. The first electrochemical device 122 may include one or more of a battery, a fuel cell, an electrolysis cell, or another electrochemical cell. The first electrochemical device 122 may include a first polarity terminal 122A, such as may include a positive terminal, and a second polarity terminal 122B, such as may include a negative terminal.

The second electrochemical device 124 may be configured similarly to the first electrochemical device 122, or may differ in one or more ways. The second electrochemical device 124 may include one or more of a battery, a fuel cell, an electrolysis cell, or another electrochemical cell. The second electrochemical device 124 may include a different type of cell than the first electrochemical device 122. For example, the first electrochemical device 122 may be one or more of a fuel cell or lithium battery, and the second electrochemical device 124 may be a lead-acid battery.

The second electrochemical device 124 may include a first polarity terminal 124A, such as may include a positive terminal, and a second polarity terminal 124B, such as may include a negative terminal. The second polarity terminal 122B of the first electrochemical device 122 may be coupled to the first polarity terminal 124A of the second electrochemical device 124, such as may result in a series combination of the first electrochemical device 122 and the second electrochemical device 124. The first electrochemical device 122 and the second electrochemical device 124 may be included in a single battery system, such as a battery module. For example, the first electrochemical device 122 and the second electrochemical device 124 may form at least a portion of a battery, such as an electric vehicle battery. A voltage of the second electrochemical device 124 may be the same as or different from the voltage of the first electrochemical device 122. For example, the first electrochemical device 122 may be a high voltage lithium battery (e.g., 100-500V) and the second electrochemical device 124 may be a standard voltage lead-acid car battery (e.g., 12V).

The energy transfer circuitry 110 may include a first switch 112, a second switch 114, and an inductor 116. The energy transfer circuitry 110 may be coupled to the controller 132, such as may allow the controller 132 to control one or more portions of the energy transfer circuitry 110. The energy transfer circuitry 110 may be configured to transfer energy between the first electrochemical device 122 and the second electrochemical device 124.

The first switch 112 may include a first conduction terminal 112A and a second conduction terminal 112B. The first switch 112 may be configured to one or more of connect or disconnect the first conduction terminal 112A and the second conduction terminal 112B based upon a signal received from the controller 132. The first switch 112 may include any type of switching circuitry. The first switch 112 may include one or more of mechanical switching circuitry (e.g., contact, solenoid, etc.) or solid-state switching circuitry (e.g. field effect transistor (FETs) or other transistor, diode, etc.).

The second switch 114 may include a first conduction terminal 114A and a second conduction terminal 114B. The second switch 114 may be configured similarly to the first switch 112 or may differ in one or more ways. The second switch 114 may be configured to one or more of connect or disconnect the first conduction terminal 114A and the second conduction terminal 114B based upon a signal received from the controller 132.

The inductor 116 may include a first inductor terminal 116A and a second inductor terminal 116B. The inductor 116 may be configured to store energy in a magnetic field generated by a current received by the inductor 116. The inductor 116 may comprise an energy storage element. In an example, the energy transfer circuitry 110 may include other energy storage elements, alternatively or in addition to the inductor 116, such as may include a capacitor.

The first conduction terminal 112A of the first switch 112 may be coupled to the first polarity terminal 122A of the first electrochemical device 122. The second conduction terminal 114B of the second switch 114 may be coupled to the second polarity terminal 124B of the second electrochemical device 124. The first switch second conduction terminal 112B of the first switch 112, the first inductor terminal 116A, and the first conduction terminal 114A of the second switch 114 may be coupled at a shared node. The second inductor terminal 116B may be coupled at the node shared by the second polarity terminal 122B of the first electrochemical device 122 and the first polarity terminal 124A of the second electrochemical device 124.

The controller 132 may include an integrated circuit (IC), a field-programmable gate array (FPGA), or any other device capable of executing computer code. The controller 132 may include flash memory, random access memory, and any other type of memory storage device. The controller 132 may be a portion of another circuit, or the tasks of the BMS may be handled by performing operations using programmed or stored instructions and a computer or other controller. The controller 132 may perform operations in addition to controlling the electrochemical excitation system 100. The controller 132 may communicate with the first switch 112 and the second switch 114 using one or more of digital or analog signals. The controller 132 may be configured to turn the first switch 112 on or off with a digital signal. The controller 132 may be configured to turn the second switch 114 on or off with a digital signal.

The controller 132 may be configured to sequence the opening and closing of the first switch 112 and the second switch 114 to transfer energy between the first electrochemical device 122 and second electrochemical device 124. To transfer energy in a first direction between the first electrochemical device 122 and the second electrochemical device 124, the controller 132 may close the first switch 112 and open the second switch 114 to generate a current in the inductor 116 from the discharging of the first electrochemical device 122. Then, the controller 132 may open the first switch 112 and close the second switch 114 to generate a charging current in the second electrochemical device 124 using the current in the inductor 116. In this way, the energy transfer circuitry 110 may transfer energy from the first electrochemical device 122 to the second electrochemical device 124.

The transfer of energy may be at least partially asynchronous. For example, the energy removed from the first electrochemical device 122 may be stored in the inductor 116 before it is transferred to the second electrochemical device 124.

To transfer energy in a second direction between the first electrochemical device 122 and the second electrochemical device 124, the controller 132 may be configured to transfer energy from the second electrochemical device 124 to the first electrochemical device 122. For example, the controller 132 may close the second switch 114 and open the first switch 112 to generate a current in the inductor 116 from the discharging of the second electrochemical device 124. Then, the controller 132 may open the second switch 114 and close the first switch 112 to generate a charging current in the first electrochemical device 122 using the current in the inductor 116.

The controller 132 may be configured to generate a discharging current in the first electrochemical device 122 and a charging current in the second electrochemical device 124 recurrently, such as may include recurrently at a specified carrier frequency. The recurrent charging and discharging currents may occur in discrete pulses, such as may include pulses separated in time. This may be due in part to the first electrochemical device 122 and the second electrochemical device 124 being isolated from the current in the inductor 116 for portions of the recurrent cycles. The discrete pulses may take one or more forms, such as may include a substantially square wave or a exponentially decaying function.

The controller 132 may generate the recurrent cycles at the specified carrier frequency for a specified number of cycles. In this way, the electrochemical excitation system 100 may generate an average current in one or more of the first electrochemical device 122 and the second electrochemical device 124 for a length of time determined by the carrier frequency and the number of cycles. The carrier frequency and number of cycles may be selected so that the length of the average current corresponds to one half period of a desired EIS excitation frequency. For example, the electrochemical excitation system 100 may generate an EIS excitation signal by generating an average current for a half period of the EIS excitation signal.

The carrier frequency may be higher than the EIS excitation frequency, such as may allow for the use of a smaller inductor 116. The carrier frequency and the EIS excitation frequency may match. The electrochemical excitation system 100 may be configured to provide a range of EIS excitation frequencies, such as may include from 0.1 Hz to 10,000 Hz. The electrochemical excitation system 100 may select the carrier frequency based upon the desired EIS excitation frequency. For example, at higher EIS excitation frequencies, the carrier frequency may match the EIS excitation frequency, while at lower frequencies, the carrier frequency may exceed the EIS excitation frequency. The carrier frequency may include 5000 Hz, 1,000 Hz, 10,000Hz, 100,000 Hz, or 1,000,000 Hz, as illustrative examples. In an example, the carrier frequency may be adjusted across a range of frequencies. For example, the carrier frequency may be swept across a specified range of frequencies to limit one or more of noise, parasitic effects, or oscillation at one or more frequencies.

In an example, the electrochemical excitation system 100 may generate an average current for one half of the EIS excitation period and remain idle for the other half of the EIS excitation period. In an example, the electrochemical excitation system 100 may generate an average current in a first direction for one half of the EIS excitation period and an average current in a second direction opposite the first direction for the other half of the EIS excitation period. One or more EIS properties may not be affected by generating more than a half-cycle waveform. One or more EIS properties may be affected when a full-cycle waveform is generated, such as may include being easier to measure as compared to when a half-cycle waveform is used.

The controller 132 may be configured to complete one or more additional tasks simultaneously with or asynchronously with generating EIS excitation signals. For example, the controller 132 may be able to charge one or more of the first electrochemical device 122 or the second electrochemical device 124, such as may include charging a smaller battery using a larger battery. The controller 132 may be configured to balance cells within or between batteries, such as may include balancing one or more cells within a battery module.

In an example, the controller 132 may be configured to receive a signal from a current sensing element in series with the inductor 116, such as may allow the controller 132 to determine an amount of energy stored in the inductor 116. This may allow the controller 132 to operate one or more of more efficiently or more reliably. A current sensing element may allow the electrochemical excitation system 100 to be smaller in size.

The controller 132 may operate without the current sensing element, such as may include using an estimated current in the inductor 116. In an example the first switch 112 may include a diode in parallel with the switch that allows current to flow from the second conduction terminal 112B to the first conduction terminal 112A. In an example, the second switch 114 may include a diode in parallel with the switch that allows current to flow from the second conduction terminal 114B to the first conduction terminal 114A. The one or more diodes may include one or more of discrete components or body diodes of a FET. The one or more diodes may allow the energy stored in the inductor 116 to be dissipated safely even if both switches 112-114 are closed. The one or more diodes may also allow the controller 132 to use a partial duty cycle for the first switch 112 and the second switch 114, such as may include both switches being open for approximately 50 percent of the carrier frequency cycle.

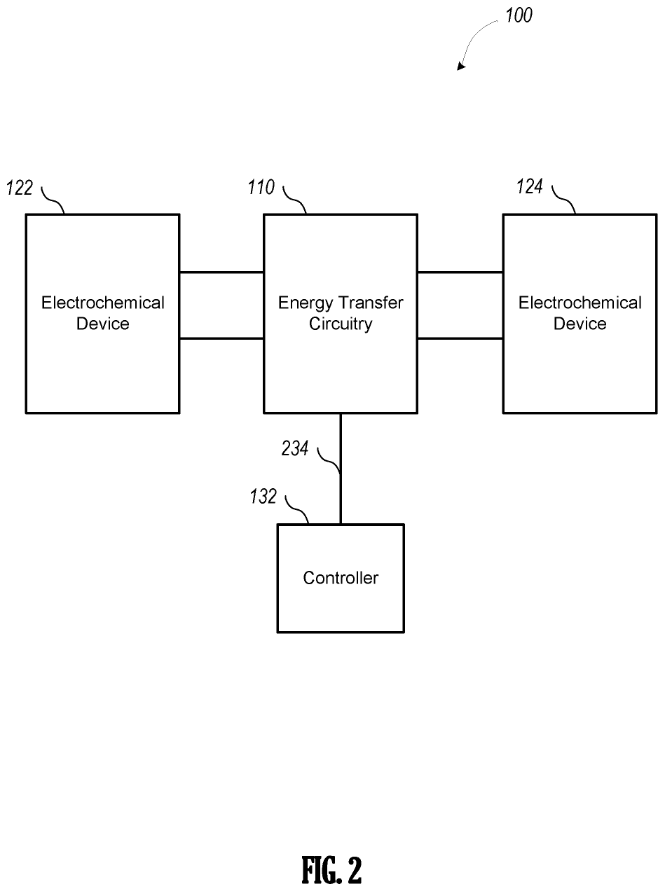

FIG. 2 is a block drawing of an example of portions of an electrochemical excitation system 100, including portions of an example of a system in which the electrochemical excitation system may be used. FIG. 2 shows that the electrochemical excitation system 100 may include energy transfer circuitry 110 and a controller 132. The environment in which the electrochemical excitation system 100 may be used may include a first electrochemical device 122 and a second electrochemical device 124.

The first electrochemical device 122 may be configured similarly to the first electrochemical device 122 of FIG. 1 or may differ in one or more ways. The second electrochemical device 124 may be configured similarly to the second electrochemical device 124 of FIG. 1 or may differ in one or more ways.

The energy transfer circuitry 110 may include DC-to-DC conversion circuitry. The energy transfer circuitry 110 may be configured to transfer energy between the first electrochemical device 122 and the second electrochemical device 124, such as may include transferring energy in a first direction, or a second direction, or both. The energy transfer circuitry 110 may be configured similarly to the energy transfer circuitry 110 of FIG. 1, or may differ in one or more ways. The energy transfer circuitry 110 may include one or more of buck converter circuitry, boost converter circuitry, buck-boost converter circuitry, buck-chopper circuitry, fly-back transformer circuitry, or other DC-to-DC conversion circuitry. The energy transfer circuitry 110 may be coupled between the first electrochemical device 122 and the second electrochemical device 124, such as may allow the energy transfer circuitry 110 to one or more of charge or discharge one or more of the first electrochemical device 122 and the second electrochemical device 124.

The controller 132 may be configured to control the energy transfer circuitry 110. The controller 132 may be coupled to the energy transfer circuitry 110 with a connection 234. The connection 234 may include a digital connection, an analog connection, or both. The controller 132 may be configured similarly to the controller 132 of FIG. 1, or may differ in one or more ways. The controller 132 may be configured to accomplish the same function as the controller 132 of FIG. 1, but may be adopted to control a different configuration of energy transfer circuitry 110. In an example, the controller 132 may send a digital excitation frequency signal to the energy transfer circuitry 110 over the connection 234.

Multiple configurations of energy transfer circuitry 110 are believed to work in the electrochemical excitation system 100, and the present disclosure is not intended to be limited to the configurations of energy transfer circuitry 110 disclosed.

The electrochemical excitation system 100 is also believed to work in the case that one of the first electrochemical device 122 or the second electrochemical device 124 is not an electrochemical device, but another source or sink of energy. For example, the second electrochemical device 124 may be a charging power source, such as may include one or more of an AC or DC electrical grid system. The electrical grid may be configured to provide and receive power, such as may allow the electrical grid to mimic a second electrochemical device 124. For example, an electric vehicle may be plugged in to wall power for one or more of storage or charging, and the electrochemical excitation system 100 may be able to generate an EIS signal by passing energy between the first electrochemical device 122 and the electrical grid in one or more directions.

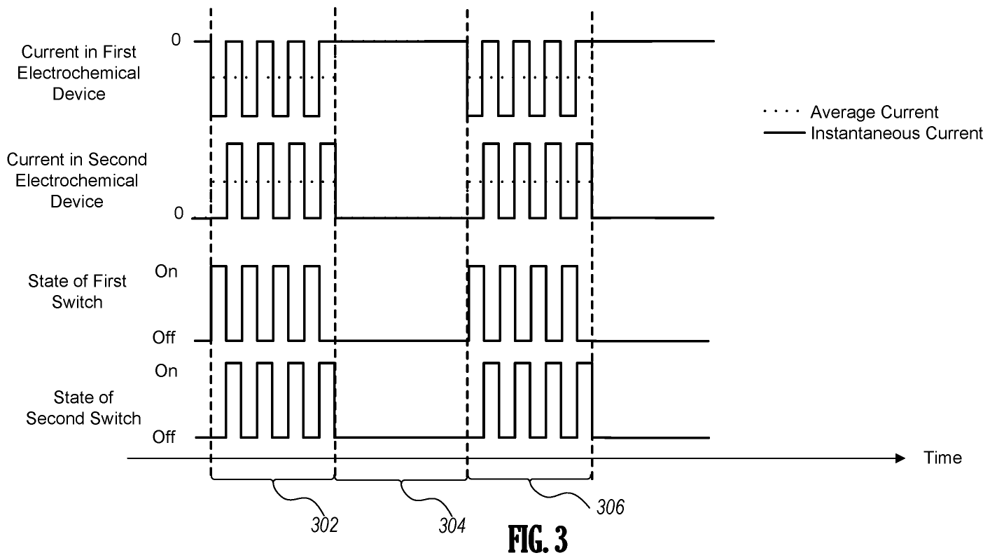

FIG. 3 is a timing diagram showing an example of operating portions of the electrochemical excitation system 100 of FIG. 1. FIG. 3 shows a first half-period 302, a second half-period 304, and a third half-period 306 for an electrochemical excitation signal. FIG. 3 shows the state of the first switch 112, the state of the second switch 114, the current in the first electrochemical device 122 (including instantaneous and average current) and the current in the second electrochemical device 124 (including instantaneous and average current).

FIG. 3 shows an example where the electrochemical excitation system 100 only actively generates one half of the excitation waveform. The first switch 112 and the second switch 114 may be initially off. There may initially be zero current in the first electrochemical device 122 and the second electrochemical device 124. After the start of the first half-period 302, the first switch 112 may turn on while the second switch 114 remains off. This may cause a discharging (negative) current in the first electrochemical device 122 as the inductor 116 stores energy. After one half period of the carrier frequency, the first switch 112 may turn off and the second switch 114 may turn on. This may generate a charging (positive) current in the second electrochemical device 124 as the inductor 116 releases energy. Then, the second switch 114 may turn off and the first switch 112 may turn on again, repeating the cycle. This may continue throughout the first half-period 302. The discrete pulses of current in the first electrochemical device 122 and the second electrochemical device 124 may generate an average discharging current in the first electrochemical device 122 and an average charging current in the second electrochemical device 124 for the first half-period 302.

Throughout the second half-period 304, the electrochemical excitation system 100 may remain idle, such as may result in zero current flowing through the first electrochemical device 122 and the second electrochemical device 124. In an example, there may be a current in one or more of the first electrochemical device 122 and the second electrochemical device 124 due to another system, such as may include one or more of a charger, a traction motor, a climate control system, an audio system, or some other system. The current may have one or more of direct current (DC) or alternating current (AC) components. For example, a traction motor may generally result in a discharge of one or more of the first electrochemical device 122 or the second electrochemical device 124, but the rate of discharge may depend on the speed or acceleration of the vehicle. The excitation signal generated by the electrochemical excitation system 100 may be superimposed on top of the current due to the one or more other systems. For example, the electrochemical excitation system 100 may operate on a battery module comprising the first electrochemical device 122 and the second electrochemical device 124 that is being discharged to power a vehicle. Both of the first electrochemical device 122 and the second electrochemical device 124 may have a DC discharge current, and the discharging of the first electrochemical device 122 caused by the electrochemical excitation system 100 may result in a faster discharge in the first electrochemical device 122 and the charging of the second electrochemical device 124 caused by the electrochemical excitation system 100 may result in a slower discharge in the second electrochemical device 124. When the signals generated by the electrochemical excitation system 100 are superimposed on the top of a DC of AC signal, the half-period waveform may mimic a full-period waveform of one-half the amplitude of the half period waveform.

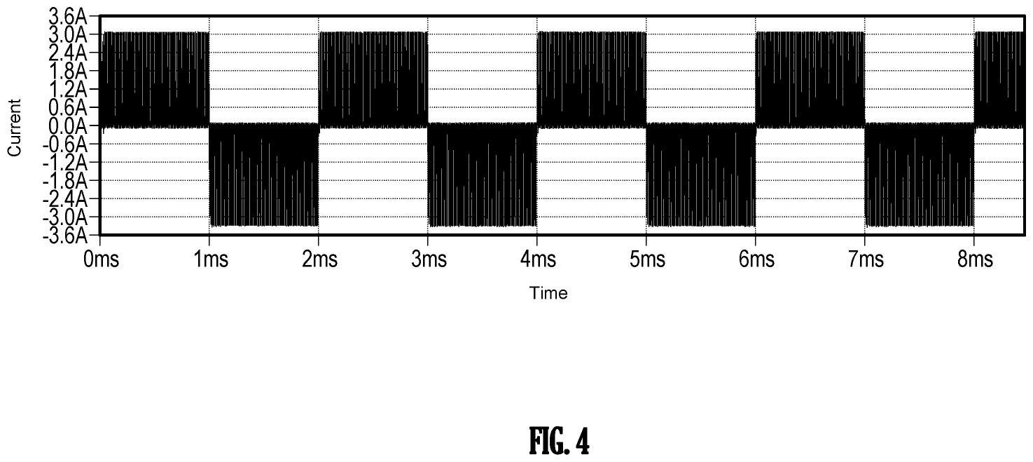

FIG. 4 is a graph in time showing an example of operating portions of the electrochemical excitation system 100 of FIG. 1. FIG. 4 shows simulated data of using the system of FIG. 1 to generate an excitation signal with an average amplitude of approximately 1.5 amps, a frequency of approximately 500 Hz, and a carrier frequency of approximately 100 kHz. FIG. 4 shows that each 1 millisecond half-period is composed of approximately 100 discrete pulses with an amplitude of approximately 3 amps, for an average current of approximately 1.5 amps. FIG. 4 shows the electrochemical excitation system 100 passing energy in a first direction and a second direction opposite the first to generate a full-cycle waveform.

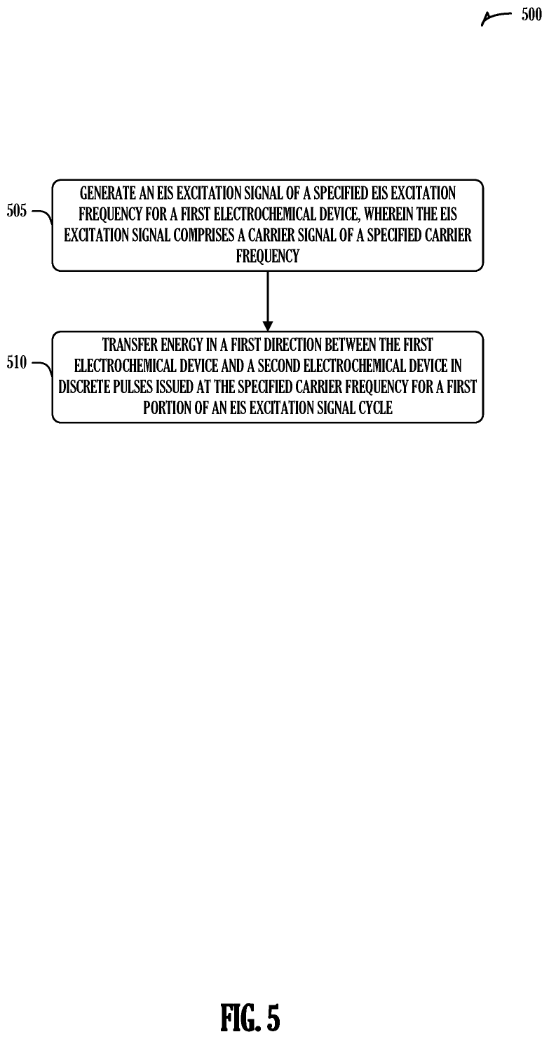

FIG. 5 is a diagram showing an example of a method 500 for operating portions of a electrochemical excitation system. At 505, an EIS excitation signal of a specified EIS excitation frequency can be generated for a first electrochemical device, wherein the EIS excitation signal comprises a carrier signal of a specified carrier frequency. At 510, the generating can include transferring energy in a first direction between the first electrochemical device and a second electrochemical device in discrete pulses issued at the specified carrier frequency for a first portion of an EIS excitation signal cycle. The shown order of steps is not intended to be a limitation on the order the steps are performed in. In an example, two or more steps may be performed simultaneously or at least partially concurrently.

The carrier frequency of step 505 may be higher than the EIS excitation frequency. The first direction of step 510 may include one or more of charging the first electrochemical device and discharging the second electrochemical device, or discharging the first electrochemical device and charging the second electrochemical device. Step 510 may include temporarily storing at least a portion of the energy transferred between the electrochemical devices. An optional step of transferring energy in a second direction opposite the first direction between the first electrochemical device and the second electrochemical device may be included. The direction may be alternated to match half-periods of the EIS excitation signal waveform.

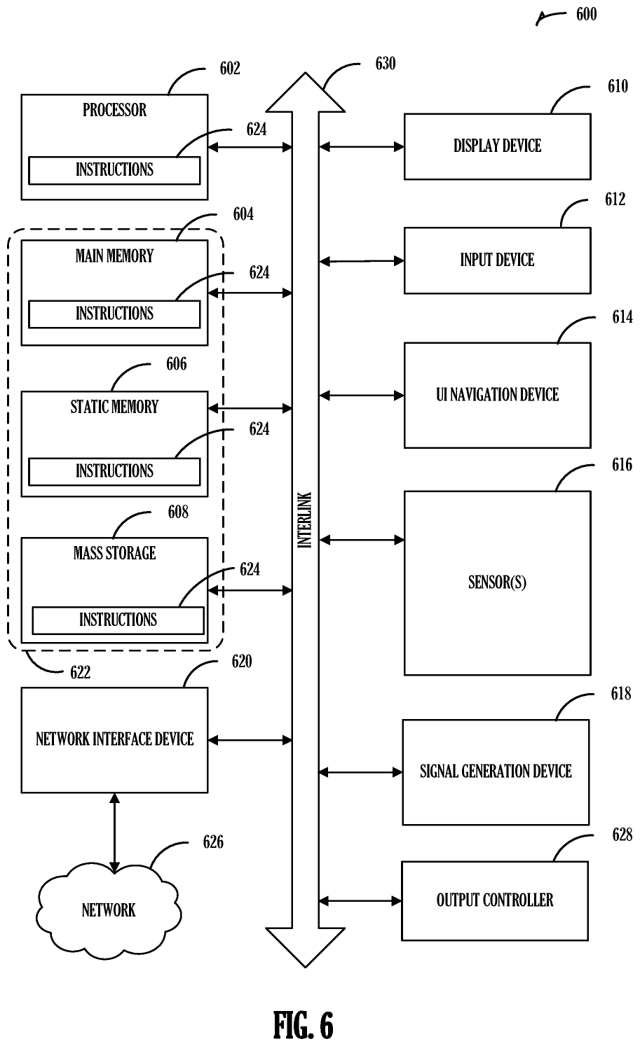

FIG. 6 is a block diagram of an example of portions of a machine 600 upon which one or more portions of the present disclosure may be implemented. Examples, as described herein, may include, or may operate by, logic or a number of components, or mechanisms in the machine 600. Circuitry (e.g., processing circuitry) is a collection of circuits implemented in tangible entities of the machine 600 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 600 follow.

In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine (e.g., computer system) 600 may include a hardware processor 602 (e.g., a central processing unit (CPU), a graphics processing unit (GPU), a hardware processor core, or any combination thereof), a main memory 604, a static memory (e.g., memory or storage for firmware, microcode, a basic-input-output (BIOS), unified extensible firmware interface (UEFI), etc.) 606, and mass storage 608 (e.g., hard drives, tape drives, flash storage, or other block devices) some or all of which may communicate with each other via an interlink (e.g., bus) 630. The machine 600 may further include a display unit 610, an alphanumeric input device 612 (e.g., a keyboard), and a user interface (UI) navigation device 614 (e.g., a mouse). In an example, the display unit 610, input device 612 and UI navigation device 614 may be a touch screen display. The machine 600 may additionally include a storage device (e.g., drive unit) 608, a signal generation device 618 (e.g., a speaker), a network interface device 620, and one or more sensors 616, such as a global positioning system (GPS) sensor, compass, accelerometer, or other sensor. The machine 600 may include an output controller 628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 602, the main memory 604, the static memory 606, or the mass storage 608 may be, or include, a machine readable medium 622 on which is stored one or more sets of data structures or instructions 624 (e.g., software) embodying or utilized by any one or more of the techniques or functions described herein. The instructions 624 may also reside, completely or at least partially, within any of registers of the processor 602, the main memory 604, the static memory 606, or the mass storage 608 during execution thereof by the machine 600. In an example, one or any combination of the hardware processor 602, the main memory 604, the static memory 606, or the mass storage 608 may constitute the machine readable media 622. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the machine 600 and that cause the machine 600 to perform any one or more of the techniques of the present disclosure, or that is capable of storing, encoding or carrying data structures used by or associated with such instructions. Non-limiting machine readable medium examples may include solid-state memories, optical media, magnetic media, and signals (e.g., radio frequency signals, other photon based signals, sound signals, etc.). In an example, a non-transitory machine readable medium comprises a machine readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 622 may be representative of the instructions 624, such as instructions 624 themselves or a format from which the instructions 624 may be derived. This format from which the instructions 624 may be derived may include source code, encoded instructions (e.g., in compressed or encrypted form), packaged instructions (e.g., split into multiple packages), or the like. The information representative of the instructions 624 in the machine readable medium 622 may be processed by processing circuitry into the instructions to implement any of the operations discussed herein. For example, deriving the instructions 624 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 624.

In an example, the derivation of the instructions 624 may include assembly, compilation, or interpretation of the information (e.g., by the processing circuitry) to create the instructions 624 from some intermediate or preprocessed format provided by the machine readable medium 622. The information, when provided in multiple parts, may be combined, unpacked, and modified to create the instructions 624. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 624 may be further transmitted or received over a communications network 626 using a transmission medium via the network interface device 620 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 802.11 family of standards known as Wi-Fi®, IEEE 802.15.4 family of standards, peer-to-peer (P2P) networks, among others. In an example, the network interface device 620 may include one or more physical jacks (e.g., Ethernet, coaxial, or phone jacks) or one or more antennas to connect to the communications network 626. In an example, the network interface device 620 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 600, and includes digital or analog communications signals or other intangible medium to facilitate communication of such software. A transmission medium is a machine readable medium.

### Additional Notes & Examples

Example 1 is an electrochemical impedance spectroscopy (EIS) excitation system, the EIS excitation system comprising: energy transfer circuitry, configured to transfer energy from a first electrochemical device to a second electrochemical device; and a controller, configured to control the energy transfer circuitry to generate an EIS excitation signal for the first electrochemical device, wherein the controller is configured to control the energy transfer circuitry to transfer energy in a first direction between the first electrochemical device and the second electrochemical device for a first portion of an EIS excitation signal cycle.

In Example 2, the subject matter of Example 1 optionally includes wherein the controller is further configured to control the energy transfer circuitry to transfer energy in discrete pulses in a second direction opposite the first direction between the second electrochemical device and the first electrochemical device for a second portion of the EIS excitation signal cycle.

In Example 3, the subject matter of any one or more of Examples 1-2 optionally include wherein the energy transfer circuitry and the controller are configured such that the transfer of energy from the first electrochemical device to the second electrochemical device is at least partially asynchronous in discrete pulses.

In Example 4, the subject matter of Example 3 optionally includes wherein the energy transfer circuitry comprises an energy storage element.

In Example 5, the subject matter of Example 4 optionally includes wherein the energy storage element includes an inductor.

In Example 6, the subject matter of any one or more of Examples 3-5 optionally include wherein a frequency of the discrete pulses is greater than a frequency of the EIS excitation signal.

In Example 7, the subject matter of any one or more of Examples 3-6 optionally include wherein a frequency of the discrete pulses is adjusted across a range of frequencies.

In Example 8, the subject matter of any one or more of Examples 3-7 optionally include wherein an EIS measurement circuit is configured to attenuate an effect of a frequency of the discrete pulses to analyze an EIS frequency of the EIS excitation signal.

In Example 9, the subject matter of any one or more of Examples 1-8 optionally include wherein the first electrochemical device includes a first number of cells and the second electrochemical device includes a second number of cells, wherein the first electrochemical device and the second electrochemical device are included in an energy storage module.

In Example 10, the subject matter of any one or more of Examples 1-9 optionally include wherein the first electrochemical device is of a different voltage than the second electrochemical device.

In Example 11, the subject matter of any one or more of Examples 1-10 optionally include wherein the first electrochemical device and the second electrochemical device include at least one of a battery cell, a fuel cell, an electrolysis cell, or other electrochemical cell.

In Example 12, the subject matter of any one or more of Examples 1-11 optionally include the first electrochemical device and the second electrochemical device.

Example 13 is a method for electrochemical impedance spectroscopy (EIS) excitation, the method comprising: generating an EIS excitation signal of a specified EIS excitation frequency for a first electrochemical device, wherein the EIS excitation signal comprises a carrier signal of a specified carrier frequency, the generating including: transferring energy in a first direction between the first electrochemical device and a second electrochemical device in discrete pulses issued at the specified carrier frequency for a first portion of an EIS excitation signal cycle.

In Example 14, the subject matter of Example 13 optionally includes wherein the generating includes: transferring energy in a second direction opposite the first direction between the second electrochemical device and the first electrochemical device in discrete pulses issued at the specified carrier frequency for a second portion of the EIS excitation signal cycle.

In Example 15, the subject matter of any one or more of Examples 13-14 optionally include wherein the transferring energy between the first electrochemical device and the second electrochemical device includes temporarily storing at least a portion of a transferred energy.

Example 16 is an electrochemical impedance spectroscopy (EIS) excitation system, the EIS excitation system comprising: an inductor, having a first inductor terminal and a second inductor terminal, wherein the first inductor terminal is coupled to a first polarity terminal of a first electrochemical device and a second polarity terminal of a second electrochemical device; a first switch, having a first conduction terminal and a second conduction terminal, wherein the first conduction terminal is coupled to a second polarity terminal of the first electrochemical device and the second conduction terminal is coupled to the second inductor terminal; and a second switch, having a third conduction terminal and a fourth conduction terminal, wherein the third conduction terminal is coupled to a first polarity terminal of the second electrochemical device and the fourth conduction terminal is coupled to the second inductor terminal.

In Example 17, the subject matter of Example 16 optionally includes a controller, configured to control the first switch and the second switch, wherein the controller is configured to generate a discharging current in the first electrochemical device and a charging current in the second electrochemical device, including to: close the first switch and open the second switch to generate a current in the inductor from the discharging of the first electrochemical device; and open the first switch and close the second switch to generate a charging current in the second electrochemical device using the current in the inductor.

In Example 18, the subject matter of Example 17 optionally includes wherein the controller is further configured to: generate a discharging current in the first electrochemical device and a charging current in the second electrochemical device recurrently at a specified carrier frequency for a specified number of cycles, thereby generating an average discharge current in the first electrochemical device and an average charge current in the second electrochemical device for a first portion of a cycle of a specified EIS excitation signal.

In Example 19, the subject matter of Example 18 optionally includes wherein the controller is further configured to generate an average charging current in the first electrochemical device and an average discharging current in the second electrochemical device for a second portion of a cycle of the specified EIS excitation signal, including to: close the second switch and open the first switch to generate a current in the inductor from the discharging of the second electrochemical device; open the second switch and close the first switch to generate a charging current in the first electrochemical device using the current in the inductor; and (1) close the second switch and open the first switch, and (2) open the second switch and close the first switch at the specified carrier frequency for the specified number of cycles.

In Example 20, the subject matter of any one or more of Examples 16-19 optionally include wherein the first switch and the second switch respectively include a field effect transistor (FET) and a diode included in or in parallel with the FET.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific embodiments in which the invention can be practiced. These embodiments are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc., are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like.

Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An electrochemical impedance spectroscopy (EIS) excitation system, the EIS excitation system comprising:
energy transfer circuitry, configured to transfer energy from a first electrochemical device to a second electrochemical device; and
a controller, configured to control the energy transfer circuitry to generate an EIS excitation signal for the first electrochemical device, wherein the controller is configured to control the energy transfer circuitry to transfer energy in a first direction between the first electrochemical device and the second electrochemical device for a first portion of an EIS excitation signal cycle.

2. The EIS excitation system of claim 1, wherein the controller is further configured to control the energy transfer circuitry to transfer energy in discrete pulses in a second direction opposite the first direction between the second electrochemical device and the first electrochemical device for a second portion of the EIS excitation signal cycle.

3. The EIS excitation system of claim 1, wherein the energy transfer circuitry and the controller are configured such that the transfer of energy from the first electrochemical device to the second electrochemical device is at least partially asynchronous in discrete pulses.

4. The EIS excitation system of claim 3, wherein the energy transfer circuitry comprises an energy storage element.

5. The EIS excitation system of claim 4, wherein the energy storage element includes an inductor.

6. The EIS excitation system of claim 3, wherein a frequency of the discrete pulses is greater than a frequency of the EIS excitation signal.

7. The EIS excitation system of claim 3, wherein a frequency of the discrete pulses is adjusted across a range of frequencies.

8. The EIS excitation system of claim 3, wherein an EIS measurement circuit is configured to attenuate an effect of a frequency of the discrete pulses to analyze an EIS frequency of the EIS excitation signal.

9. The EIS excitation system of claim 1, wherein the first electrochemical device includes a first number of cells and the second electrochemical device includes a second number of cells, wherein the first electrochemical device and the second electrochemical device are included in an energy storage module.

10. The EIS excitation system of claim 1, wherein the first electrochemical device is of a different voltage than the second electrochemical device.

11. The EIS excitation system of claim 1, wherein the first electrochemical device and the second electrochemical device include at least one of a battery cell, a fuel cell, an electrolysis cell, or other electrochemical cell.

12. The EIS excitation system of claim 1, further comprising the first electrochemical device and the second electrochemical device.

13. A method for electrochemical impedance spectroscopy (EIS) excitation, the method comprising:
generating an EIS excitation signal of a specified EIS excitation frequency for a first electrochemical device, wherein the EIS excitation signal comprises a carrier signal of a specified carrier frequency, the generating including:
transferring energy in a first direction between the first electrochemical device and a second electrochemical device in discrete pulses issued at the specified carrier frequency for a first portion of an EIS excitation signal cycle.

14. The method of claim 13, wherein the generating includes:
transferring energy in a second direction opposite the first direction between the second electrochemical device and the first electrochemical device in discrete pulses issued at the specified carrier frequency for a second portion of the EIS excitation signal cycle.

15. The method of claim 13, wherein the transferring energy between the first electrochemical device and the second electrochemical device includes temporarily storing at least a portion of a transferred energy.

16. An electrochemical impedance spectroscopy (EIS) excitation system, the EIS excitation system comprising:
an inductor, having a first inductor terminal and a second inductor terminal, wherein the first inductor terminal is coupled to a first polarity terminal of a first electrochemical device and a second polarity terminal of a second electrochemical device;
a first switch, having a first conduction terminal and a second conduction terminal, wherein the first conduction terminal is coupled to a second polarity terminal of the first electrochemical device and the second conduction terminal is coupled to the second inductor terminal; and
a second switch, having a third conduction terminal and a fourth conduction terminal, wherein the third conduction terminal is coupled to a first polarity terminal of the second electrochemical device and the fourth conduction terminal is coupled to the second inductor terminal.

17. The EIS excitation system of claim 16, comprising:
a controller, configured to control the first switch and the second switch, wherein the controller is configured to generate a discharging current in the first electrochemical device and a charging current in the second electrochemical device, including to:
close the first switch and open the second switch to generate a current in the inductor from the discharging of the first electrochemical device; and
open the first switch and close the second switch to generate a charging current in the second electrochemical device using the current in the inductor.

18. The EIS excitation system of claim 17, wherein the controller is further configured to:
generate a discharging current in the first electrochemical device and a charging current in the second electrochemical device recurrently at a specified carrier frequency for a specified number of cycles, thereby generating an average discharge current in the first electrochemical device and an average charge current in the second electrochemical device for a first portion of a cycle of a specified EIS excitation signal.

19. The EIS excitation system of claim 18, wherein the controller is further configured to generate an average charging current in the first electrochemical device and an average discharging current in the second electrochemical device for a second portion of a cycle of the specified EIS excitation signal, including to:
close the second switch and open the first switch to generate a current in the inductor from the discharging of the second electrochemical device;
open the second switch and close the first switch to generate a charging current in the first electrochemical device using the current in the inductor; and
(1) close the second switch and open the first switch, and (2) open the second switch and close the first switch at the specified carrier frequency for the specified number of cycles.

20. The EIS excitation system of claim 16, wherein the first switch and the second switch respectively include a field effect transistor (FET) and a diode included in or in parallel with the FET.
